(19) United States
(12) Patent Application Publication
(10) Pub. No.: US 2025/0380380 A1
(43) Pub. Date: Dec. 11, 2025

(54) LIQUID COOLING DEVICE

(71) Applicants: INVENTEC (PUDONG) TECHNOLOGY CORPORATION, Shanghai (CN); INVENTEC CORPORATION, Taipei City (TW)

(72) Inventors: Kai-Yang TUNG, Taipei City (TW); Hung-Ju CHEN, Taipei City (TW); Yin Po CHIU, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 18/945,374

(22) Filed: Nov. 12, 2024

(30) Foreign Application Priority Data
Jun. 5, 2024 (CN) 202410727622.8

(51) Int. Cl. H05K 7/20

(52) U.S. Cl. CPC H05K 7/20272; H05K 7/20254; H05K 7/20309; H05K 7/20318; H05K 7/20327

(57) ABSTRACT

A liquid cooling device comprises a first cold plate, a second cold plate and two connection pipes. The second cold plate is stacked on the first cold plate. The two connection pipes are disposed on opposite sides of the first cold plate and the second cold plate, respectively, and protrude from the first cold plate and the second cold plate. The two connection pipes are connected to the first cold plate and the second cold plate.

### CROSS-REFERENCE TO RELATED APPLICATIONS

This non-provisional application claims priority under 35 U.S.C. § 119 (a) on Patent Application No(s). 202410727622.8 filed in China, on Jun. 5, 2024, the entire contents of which are hereby incorporated by reference.

### BACKGROUND OF THE INVENTION

### Technical Field of the Invention

The invention relates to a liquid cooling device, more particularly to a liquid cooling device provided with two cold plates and two connection pipes.

### Description of the Related Art

The operation of electronic devices generates a significant amount of heat. If the heat cannot be effectively dissipated, the internal electronic components may overheat, leading to malfunctions or system crashes. Therefore, electronic devices typically have corresponding heat dissipation systems to ensure that the components do not operate beyond a preset temperature range. Particularly for high-performance electronic devices, liquid cooling heat dissipation systems, such as cold plates, are commonly employed to provide more effective heat dissipation.

A conventional liquid cooling heat dissipation system includes a condenser disposed between two cold plates to achieve more uniform heat dissipation. In general, the middle sections at one side of the two cold plates are connected through an external protruding connection pipe. However, this configuration creates fragmented spaces on either side of the protruding connection pipe, which limits the placement of other electronic components in the electronic device, thereby reducing the space utilization in the electronic device. To address this issue, some manufacturers have reduced the size of the condenser to place the connection pipe between the two cold plates. However, smaller condensers result in insufficient heat dissipation efficiency. As a result, the challenge for researchers is how to increase the space utilization in the electronic device while maintaining the heat dissipation efficiency of the liquid cooling heat dissipation system.

### SUMMARY OF THE INVENTION

The invention provides a liquid cooling device, which is capable of improving the space utilization in a server while maintaining its heat dissipation efficiency.

One embodiment of the invention provides a liquid cooling device including a first cold plate, a second cold plate and two connection pipes. The second cold plate is stacked on the first cold plate. The two connection pipes are respectively disposed on opposite sides of the first cold plate and the second cold plate, and protruding from the first cold plate and the second cold plate. The two connection pipes are connected to the first cold plate and the second cold plate.

According to the liquid cooling device in the above embodiment, since the two connection pipes are respectively disposed on opposite sides of the first cold plate and the second cold plate, fragmented spaces may be reduced, thereby improving the space utilization in the server.

In addition, since the two connection pipes protrude from the first cold plate and the second cold plate without occupying the space allocated for the condenser, there is no need to reduce the size of the condenser. As a result, the heat dissipation efficiency of the liquid cooling device may be maintained.

The above description of the content and the following description of the embodiments of the invention, are intended to illustrate and explain the principles of the invention and to further clarify the scope of the claims of the invention.

### BRIEF DESCRIPTION OF THE DRAWINGS

The invention will become more fully understood from the detailed description given hereinbelow and the accompanying drawings which are given by way of illustration only and thus are not limitative of the invention and wherein:

FIG. 1 is a schematic perspective view of a liquid cooling device according to one embodiment of the invention;

FIG. 2 is another schematic perspective view of the liquid cooling device in FIG. 1;

FIG. 3 is a cross-sectional view of a first cold plate of the liquid cooling device in FIG. 1;

FIG. 4 is a cross-sectional view of a connection pipe of the liquid cooling device taken along line 4-4 in FIG. 3; and

FIG. 5 is a cross-sectional view of a second cold plate of the liquid cooling device in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have their own meanings and can be comprehended by those skilled in the art, unless the terms are further defined in the invention. That is, the terms used in the following paragraphs should be read on the meaning commonly used in the related fields and will not be overly explained, unless the terms have a specific meaning in the invention.

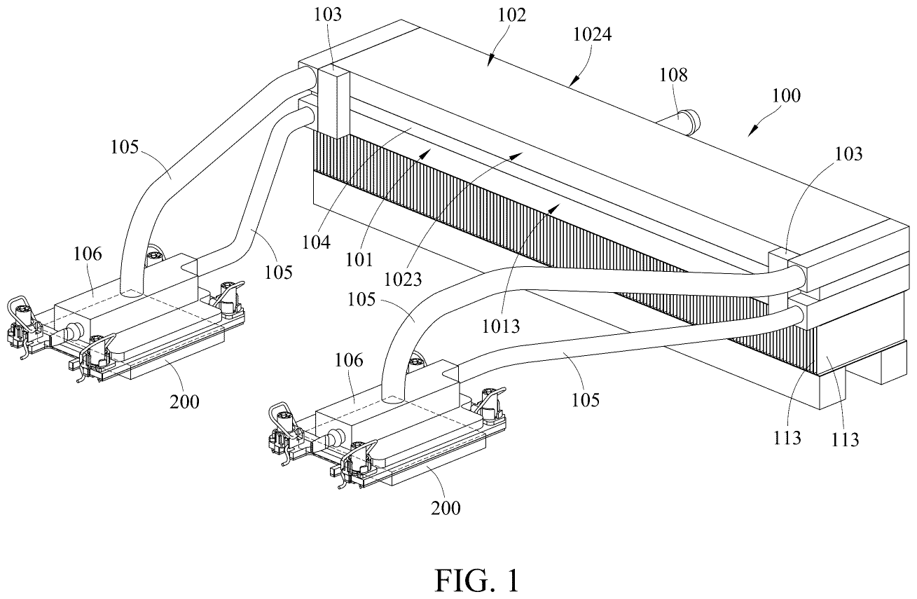

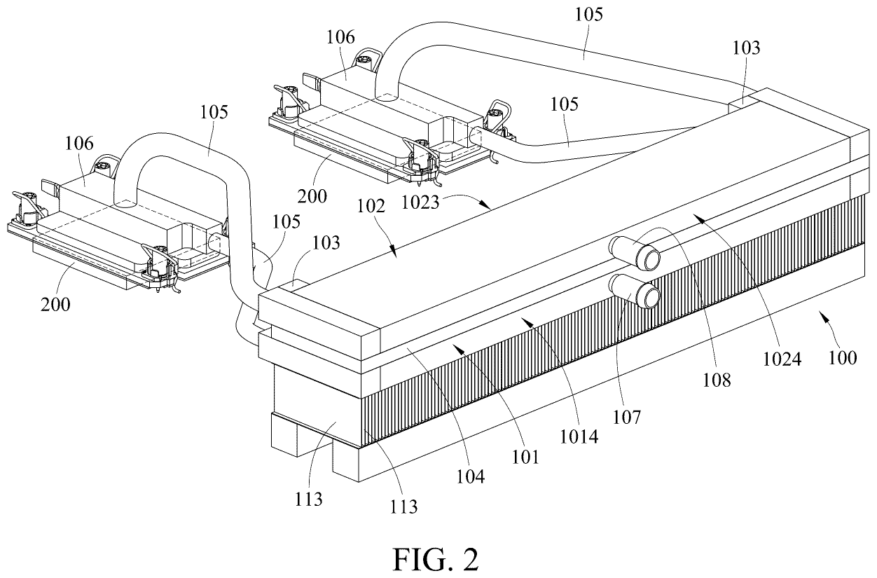

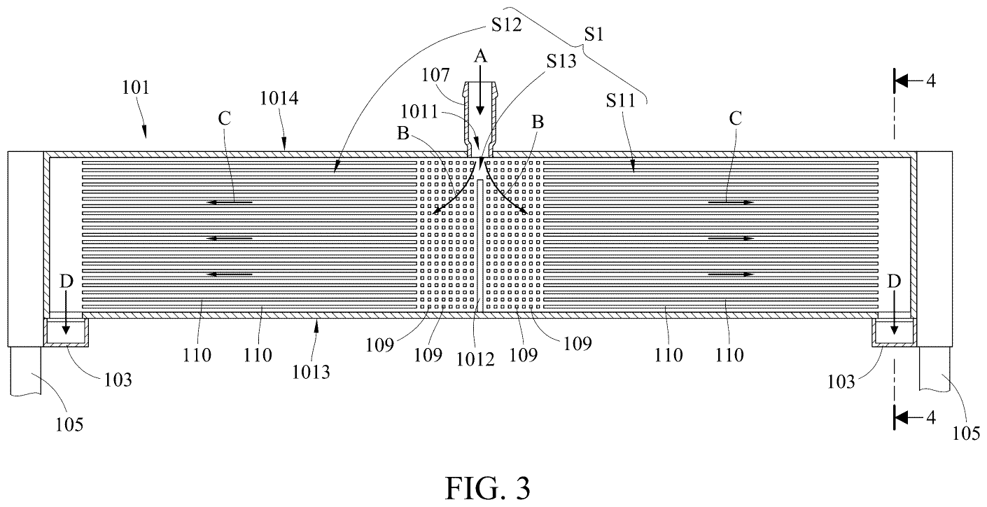

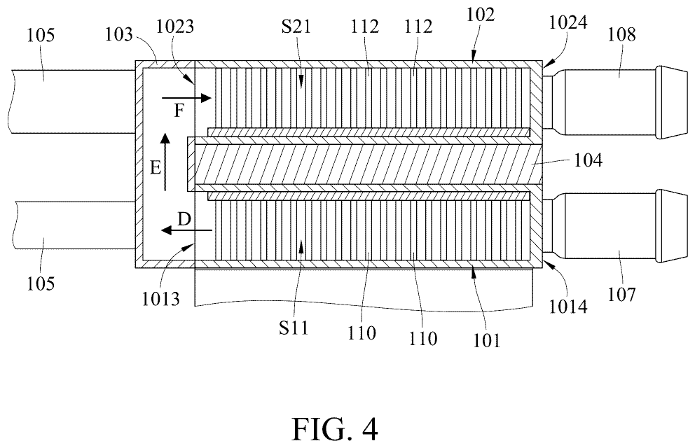

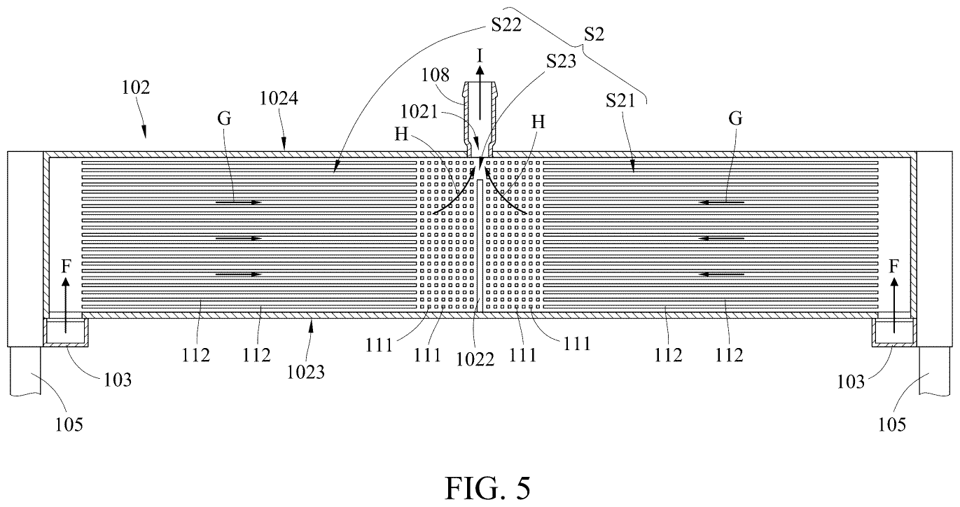

Referring to FIG. 1 to FIG. 5. FIG. 1 is a schematic perspective view of a liquid cooling device according to one embodiment of the invention. FIG. 2 is another schematic perspective view of the liquid cooling device in FIG. 1. FIG. 3 is a cross-sectional view of a first cold plate of the liquid cooling device in FIG. 1. FIG. 4 is a cross-sectional view of a connection pipe of the liquid cooling device taken along line 4-4 in FIG. 3. FIG. 5 is a cross-sectional view of a second cold plate of the liquid cooling device in FIG. 1.

In this embodiment, a liquid cooling device 100 is configured to be disposed in a server (not shown) and includes a first cold plate 101, a second cold plate 102, two connection pipes 103, a condenser 104, a plurality of thermosiphon pipes 105, two evaporators 106, a liquid inlet pipe 107 and a liquid outlet pipe 108. The first cold plate 101 and second cold plate 102 are configured to accommodate a first cooling liquid (not shown). The second cold plate 102 is stacked on the first cold plate 101.

The first cold plate 101 has a first side 1013 and a second side 1014 that are opposite to each other. The second cold plate 102 has a third side 1023 and a fourth side 1024 that are opposite to each other. The two connection pipes 103 are respectively disposed on opposite sides of the first cold plate 101 and the second cold plate 102, and protruding from the first side 1013 of the first cold plate 101 and the third side 1023 of the second cold plate 102. The two connection pipes 103 are connected to the first cold plate 101 and the second cold plate 102, and are configured to allow the first cooling liquid to flow from the first cold plate 101 to the second cold plate 102.

The second side 1014 of the first cold plate 101 has a liquid inlet 1011. That is, the liquid inlet 1011 and the connection pipes 103 are respectively located on opposite sides of the first cold plate 101. The liquid inlet pipe 107 is disposed on the liquid inlet 1011 and is configured to allow the first cooling liquid to flow therein. The fourth side 1024 of the second cold plate 102 has a liquid outlet 1021. That is, the liquid outlet 1021 and the connection pipes 103 are located on opposite sides of the second cold plate 102. The liquid outlet pipe 108 is disposed on the liquid outlet 1021 and is configured to allow the first cooling liquid to flow therein. In addition, the first cooling liquid, for example, may be water, but the invention is not limited thereto.

The condenser 104, the thermosiphon pipes 105, and the two evaporators 106 are configured to accommodate a second cooling liquid (not shown). The condenser 104 is disposed between the first cold plate 101 and the second cold plate 102. Specifically, the first cold plate 101 is located at a bottom of the condenser 104, and the second cold plate 102 is located at a top of the condenser 104. The thermosiphon pipes 105 are respectively connected to opposite ends of the condenser 104. The two evaporators 106 are respectively connected to ends of the thermosiphon pipes 105 that are away from the condenser 104. The two evaporators 106 are configured to be thermally coupled to two heat sources 200. The term “thermally coupled” refers to thermal contact or connection through other thermally conductive media. In addition, “thermosiphon” refers to the process where liquid coolant is partially vaporized to form a gas-liquid mixture after being heated, and the density difference between the liquid coolant and gas coolant serves as the driving force for the cooling circulation. Moreover, the second cooling liquid is, for example, a refrigerant, and the heat sources 200 are, for example, CPUs, but the invention is not limited thereto.

When the second cooling liquid absorbs a heat generated by the two heat sources 200 at the two evaporators 106 and flows to the condenser 104 through the thermosiphon pipes 105, the first cooling liquid may absorb and carry away the heat transferred to the second cooling liquid via flowing through the first cold plate 101, the two connection pipes 103, and the second cold plate 102. In this way, the heat from the two heat sources 200 can be dissipated.

In this embodiment, since the two connection pipes 103 are respectively disposed on opposite sides of the first cold plate 101 and the second cold plate 102, and are respectively adjacent to the thermosiphon pipes 105, the two connection pipes 103 may be structurally integrated with the thermosiphon pipes 105 to reduce fragmented spaces, thereby improving the space utilization in the server.

In addition, since the two connection pipes 103 protrude from the first cold plate 101 and the second cold plate 102 without occupying the space allocated for the condenser 104, there is no need to reduce the size of the condenser 104. As a result, the heat dissipation efficiency of the liquid cooling device 100 is maintained.

In this embodiment, structure of the first cold plate 101 is, for example, the same as that of the second cold plate 102. Specifically, the first cold plate 101 has a first accommodation space S1, and the first cold plate 101 includes a first partition 1012. The first partition 1012 is located in the first accommodation space S1 and divides the first accommodation space S1 into a first accommodation subspace S11 and a second accommodation subspace S12. The first accommodation space S1 has a flow distribution subspace S13. The flow distribution subspace S13 is connected to the liquid inlet 1011. The first accommodation subspace S11 and the second accommodation subspace S12 are in fluid communication with each other through the flow distribution subspace S13. In this way, the first cooling liquid flowing into the first accommodation space S1 may be distributed. In addition, the configuration in the first cold plate 101 is, for example, a symmetrical structure.

The second cold plate 102 has a second accommodation space S2, and the second cold plate 102 includes a second partition 1022. The second partition 1022 is located in the second accommodation space S2 and divides the second accommodation space S2 into a third accommodation subspace S21 and a fourth accommodation subspace S22. The second accommodation space S2 has a confluence subspace S23. The confluence subspace S23 is connected to the liquid outlet 1021. The third accommodation subspace S21 and the fourth accommodation subspace S22 are in fluid communication with each other through the confluence subspace S23. The first accommodation subspace S11 is connected to the third accommodation subspace S21 through one of the two connection pipes 103. The second accommodation subspace S12 is connected to the fourth accommodation subspace S22 through the other of the two connection pipes 103. That is, after the first cooling liquid flows into the first accommodation space S1, it may be divided into two independent circulation flows. In addition, the configuration in the second cold plate 102 is, for example, a symmetrical structure.

The liquid cooling device 100 includes a plurality of first columnar fins 109, a plurality of first plate fins 110, a plurality of second columnar fins 111, and a plurality of second plate fins 112. The first columnar fins 109 are respectively located in the first accommodation subspace S11 and the second accommodation subspace S12. The first plate fins 110 are respectively located in the first accommodation subspace S11 and the second accommodation subspace S12. The first columnar fins 109 are located closer to the first partition 1012 than the first plate fins 110. In addition, an extension direction of each of the first plate fins 110 is, for example, perpendicular to an extension direction of the first partition 1012, but the invention is not limited thereto. In addition, a thickness of each of the first columnar fins 109 and a thickness of each of the first plate fins 110 are approximately 0.3 mm, and a distance between adjacent two of the first columnar fins 109 and a distance between adjacent two of the first plate fins 110 are approximately 1.5 mm.

The second columnar fins 111 are respectively located in the third accommodation subspace S21 and the fourth accommodation subspace S22. The second plate fins 112 are respectively located in the third accommodation subspace S21 and the fourth accommodation subspace S22. The second columnar fins 111 are located closer to the second partition 1022 than the second plate fins 112. In addition, an extension direction of each of the second plate fins 112 is, for example, perpendicular to an extension direction of the second partition 1022, but the invention is not limited thereto. In addition, a thickness of each of the second columnar fins 111 and a thickness of each of the second plate fins 112 are approximately 0.3 mm, and a distance between adjacent two of the second columnar fins 111 and a distance between adjacent two of the second plate fins 112 are approximately 1.5 mm.

In this embodiment, since the liquid cooling device 100 is provided with the first columnar fins 109 having smaller size near the first partition 1012, and the second columnar fins 111 having smaller size near the second partition 1022, when the first cooling liquid flows into the first accommodation space S1 and flows out of the second accommodation space S2, it provides a wider space for the first cooling liquid to change its flow direction, allowing the first cooling liquid to flow uniformly in the first accommodation space S1 and the second accommodation space S2, thereby improving cooling efficiency.

In addition, due to the presence of the first partition 1012, after the first cooling liquid flows into the first accommodation space S1, two independent circulation flows are formed in the first accommodation subspace S11 and the second accommodation subspace S12, respectively. The configuration of the columnar fins and plate fins in the first accommodation subspace S11 and the second accommodation subspace S12 can be adjusted based on the heat dissipation requirements of the heat sources 200, thereby reducing the temperature difference between the two heat sources.

In addition, since the liquid cooling device 100 is provided with the first plate fins 110 having larger heat exchange areas away from the first partition 1012, and the second plate fins 112 having larger heat exchange areas away from the second partition 1022, cooling efficiency is further improved. Furthermore, since the manufacturing method of the first plate fins 110 and the second plate fins 112 is relatively simple, production costs can be reduced. On the other hand, the pressure drop of the first cooling liquid may be reduced through the inclusion of the two connection pipes 103, the first columnar fins 109, the second columnar fins 111, the first plate fins 110, and the second plate fins 112. In this way, the flow resistance of the first cooling liquid can be reduced, thereby further improving heat dissipation efficiency. For example, compared to a conventional liquid cooling device (where the connection pipe is placed in the middle of one side of the two cold plates), the liquid cooling device 100 in this embodiment may reduce the pressure drop of the first cooling liquid, for example, from 475.9 Pascal (Pa) to 295.4 Pa. That is, the liquid cooling device 100 in this embodiment may reduce the pressure drop of the first cooling liquid, for example, by approximately 180.5 Pa.

In this embodiment, the liquid cooling device 100 may also include a plurality of external fins 113. The external fins 113 are disposed on a side of the first cold plate 101 that is away from the second cold plate 102. In this way, an airflow generated by a fan (not shown) of the server passing through the external fins 113 can further improve the cooling efficiency. The temperature of the airflow generated by the fan of server passing through the external fins 113 can be reduced, for example, by approximately 5.9° C. through the inclusion of the two connection pipes 103, the first columnar fins 109, the second columnar fins 111, the first plate fins 110, the second plate fins 112, and the external fins 113.

In this embodiment, the first cold plate 101, located at the bottom of the condenser 104, is configured to allow the first cooling liquid to flow in, and the second cold plate 102, located at the top of the condenser 104, is configured to allow the first cooling liquid to flow out, but the invention is not limited thereto. In other embodiments, the flow direction of the first cooling liquid can also be reversed. That is, the second cold plate located at the top of the condenser can allow the first cooling liquid to flow in, and the first cold plate located at the bottom of the condenser can allow the first cooling liquid to flow out.

In this embodiment, the configuration in the first cold plate 101 is symmetrical, and the configuration in the second cold plate 102 is symmetrical, but the invention is not limited thereto. In other embodiments, when adjustments to the structure of the thermosiphon pipes are required due to different server configurations, the configuration in the first cold plate and the second cold plate can also be adjusted based on the structure of the thermosiphon pipes.

In this embodiment, the first columnar fins 109 and the second columnar fins 111 are column-shaped, and the first plate fins 110 and the second plate fins 112 are plate-shaped, but the invention is not limited thereto. In other embodiments, the fins disposed in the first accommodation space and the second accommodation space may also be, for example, in other forms,

Please refer again to FIGS. 3 to 5. In this embodiment, when the first cooling liquid flows into the first accommodation space S1 from the liquid inlet pipe 107 in a direction A, the first cooling liquid in the flow distribution subspace S13 respectively flows into the first accommodation subspace S11 and the second accommodation subspace S12 in a direction B firstly. Then, the first cooling liquid, after being distributed, respectively flows in the first accommodation subspace S11 and the second accommodation subspace S12 in a direction C. Then, the first cooling liquid, after being distributed, respectively flows to the two connection pipes 103 in a direction D and then flows in the two connection pipes 103 in a direction E.

Then, the first cooling liquid, after being distributed, respectively flows from the two connection pipes 103 into the third accommodation subspace S21 and the fourth accommodation subspace S22 in a direction F. Then, the first cooling liquid, after being distributed, respectively flows in the third accommodation subspace S21 and the fourth accommodation subspace S22 in a direction G. Then, the first cooling liquid, after being distributed, respectively flows to the confluence subspace S23 in a direction H, and converges in the confluence subspace S23. Then, the first cooling liquid, after being converged, flows from the second accommodation space S2 to the liquid outlet pipe 108 in a direction I, and initiating a next circulation. In this way, the cooling circulation of the first cooling liquid may be completed.

According to the liquid cooling device the above embodiment, since the two connection pipes are respectively disposed on opposite sides of the first cold plate and the second cold plate, and are respectively adjacent to the thermosiphon pipes, the two connection pipes may be structurally integrated with the thermosiphon pipes to reduce fragmented spaces, thereby improving the space utilization in the server.

In addition, since the two connection pipes protrude from the first cold plate and the second cold plate without occupying the space allocated for the condenser, there is no need to reduce the size of the condenser. As a result, the heat dissipation efficiency of the liquid cooling device may be maintained.

In addition, since the liquid cooling device is provided with the first columnar fins having smaller size near the first partition, and the second columnar fins having smaller size near the second partition, when the first cooling liquid flows into the first accommodation space and flows out from the second accommodation space, it provides a wider space for the first cooling liquid to change its flow direction, allowing the first cooling liquid to flow uniformly in the first accommodation space and the second accommodation space, thereby improving cooling efficiency.

In addition, since the liquid cooling device is provided with the first plate fins having larger heat exchange areas away from the first partition, and the second plate fins having larger heat exchange areas away from the second partition, cooling efficiency is further improved. Further, since the manufacturing method of the first plate fins and the second plate fins is relatively simple, production costs can be reduced.

On the other hand, the pressure drop of the first cooling liquid may be reduced through the inclusion of the two connection pipes, the first columnar fins, the second columnar fins, the first plate fins, and the second plate fins. In this way, the flow resistance of the first cooling liquid may be reduced, thereby further improving heat dissipation efficiency.

In one embodiment of the invention, the liquid cooling device according to the invention can be used in a server, where the server can be applied to artificial intelligence (AI) computing, edge computing, as well as a 5G server, a cloud server, or a server for vehicle-to-everything.

Although the invention has been disclosed through the aforementioned embodiments, it is not intended to limit the scope of the invention. Those skilled in the art may make various modifications and adjustments without departing from the spirit and scope of the invention. Therefore, the scope of patent protection for the invention shall be defined by the following claims of the specification.

What is claimed is:

1. A liquid cooling device, comprising:
a first cold plate;
a second cold plate, stacked on the first cold plate; and
two connection pipes, respectively disposed on opposite sides of the first cold plate and the second cold plate, and protruding from the first cold plate and the second cold plate, wherein the two connection pipes are connected to the first cold plate and the second cold plate.

2. The liquid cooling device according to claim 1, wherein the first cold plate has a liquid inlet on a side of the first cold plate away from the two connection pipes, and the second cold plate has a liquid outlet on a side of the second cold plate away from the two connection pipes.

3. The liquid cooling device according to claim 2, wherein the first cold plate has a first accommodation space, the first cold plate comprises a first partition located in the first accommodation space and dividing the first accommodation space into a first accommodation subspace and a second accommodation subspace, the first accommodation space has a flow distribution subspace connected to the liquid inlet, and the first accommodation subspace and the second accommodation subspace are in fluid communication with each other through the flow distribution subspace.

4. The liquid cooling device according to claim 3, further comprising a plurality of first columnar fins and a plurality of first plate fins, wherein the plurality of first columnar fins are respectively located in the first accommodation subspace and the second accommodation subspace, the plurality of first plate fins are respectively located in the first accommodation subspace and the second accommodation subspace, and the plurality of first columnar fins are located closer to the first partition than the plurality of first plate fins.

5. The liquid cooling device according to claim 4, wherein an extension direction of each of the plurality of first plate fins is perpendicular to an extension direction of the first partition.

6. The liquid cooling device according to claim 4, wherein the second cold plate has a second accommodation space, the second cold plate comprises a second partition located in the second accommodation space and dividing the second accommodation space into a third accommodation subspace and a fourth accommodation subspace, the second accommodation space has a confluence subspace connected to the liquid outlet, the third accommodation subspace and the fourth accommodation subspace are in fluid communication with each other through the confluence subspace, the first accommodation subspace is connected to the third accommodation subspace through one of the two connection pipes, and the second accommodation subspace is connected to the fourth accommodation subspace through other of the two connection pipes.

7. The liquid cooling device according to claim 6, further comprising a plurality of second columnar fins and a plurality of second plate fins, wherein the plurality of second columnar fins are respectively located in the third accommodation subspace and the fourth accommodation subspace, the plurality of second plate fins are respectively located in the third accommodation subspace and the fourth accommodation subspace, and the plurality of second columnar fins are located closer to the second partition than the plurality of second plate fins.

8. The liquid cooling device according to claim 7, wherein an extension direction of each of the plurality of second plate fins is perpendicular to an extension direction of the second partition.

9. The liquid cooling device according to claim 1, further comprising a condenser, a plurality of thermosiphon pipes and two evaporators, wherein the condenser is disposed between the first cold plate and the second cold plate, the plurality of thermosiphon pipes are respectively connected to two opposite ends of the condenser, the two evaporators are respectively connected to one end of the plurality of thermosiphon pipes away from the condenser, and the two evaporators are configured to be thermally coupled to two heat sources.

10. The liquid cooling device according to claim 1, further comprising a plurality of external fins disposed on a side of the first cold plate away from the second cold plate.
